(19) United States
(12) Patent Application Publication
(10) Pub. No.: US 2017/0141123 A1
(43) Pub. Date: May 18, 2017

(54) SEMICONDUCTOR MEMORY DEVICE AND METHOD FOR MANUFACTURING SAME

(71) Applicant: Kabushiki Kaisha Toshiba, Minato-ku (JP)

(72) Inventors: Yosuke MITSUNO, Yokkaichi (JP); Hiroshi Kanno, Yokkaichi (JP); Makoto Fujiwara, Yokkaichi (JP)

(73) Assignee: Kabushiki Kaisha Toshiba, Minato-ku (JP)

(21) Appl. No.: 15/055,813

(22) Filed: Feb. 29, 2016

Related U.S. Application Data
(60) Provisional application No. 62/256,451, filed on Nov. 17, 2015.

(51) Int. Cl. H01L 27/115; H01L 29/165; H01L 29/04; H01L 21/3065; H01L 21/324

(52) U.S. Cl. CPC H01L 27/11582; H01L 21/3065; H01L 21/324; H01L 29/04; H01L 29/165

(57) ABSTRACT

According to one embodiment, a semiconductor memory device includes a substrate; a stacked body including a plurality of electrode layers; a first semiconductor film including a first portion and a second portion; a first insulating film having a lower surface; and a second semiconductor film having a lower surface. The first portion is provided as one body inside the stacked body. The first portion has a first crystal structure different from a crystal structure of the substrate. The second portion is provided between the first portion and the substrate. The second portion contacts the substrate and has a second crystal structure different from the first crystal structure.

### CROSS-REFERENCE TO RELATED APPLICATIONS

This application is based upon and claims the benefit of priority from U.S. Provisional Patent Application 62/256,451 field on Nov. 17, 2015; the entire contents of which are incorporated herein by reference.

### FIELD

Embodiments described herein relate generally to a semiconductor memory device and a method for manufacturing same.

### BACKGROUND

A memory device has been proposed in which multiple memory cells are provided in a three-dimensional structure and stacked with insulating layers interposed.

The improvement of the electrical characteristics of the device recited above is a challenge.

### BRIEF DESCRIPTION OF THE DRAWINGS

FIG. 1 is a schematic perspective view of a memory cell array of an embodiment;

FIG. 2 is a schematic cross-sectional view of the semiconductor memory device of the embodiment;

FIG. 3A is an enlarged schematic cross-sectional view of a columnar portion of the embodiment, and FIG. 3B is a schematic cross-sectional view of the semiconductor memory device of the embodiment; and

FIG. 4 to FIG. 7B are schematic cross-sectional views showing a method for manufacturing the semiconductor memory device of the embodiment.

### DETAILED DESCRIPTION

According to one embodiment, a semiconductor memory device includes a substrate; a stacked body provided on the substrate, the stacked body including a plurality of electrode layers stacked with an insulating layer interposed; a first semiconductor film provided as one body inside the stacked body and inside the substrate, the first semiconductor film extending in a stacking direction of the stacked body, the first semiconductor film including a first portion and a second portion; a first insulating film provided between the first semiconductor film and the stacked body, the first insulating film extending in the stacking direction and having a lower surface contacting the second portion, the lower surface being provided at a height not higher than a height of a surface of the substrate contacting the stacked body; and a second semiconductor film provided between the first insulating film and the first portion of the first semiconductor film, the second semiconductor film extending in the stacking direction and having a lower surface provided at a height lower than the height of the lower surface of the first insulating film. The first portion is provided as one body inside the stacked body. The first portion has a first crystal structure different from a crystal structure of the substrate. The second portion is provided between the first portion and the substrate. The second portion contacts the substrate and has a second crystal structure different from the first crystal structure.

Embodiments are described below with reference to the drawings. Note that in the drawings, the same components are denoted by the same reference numerals and signs.

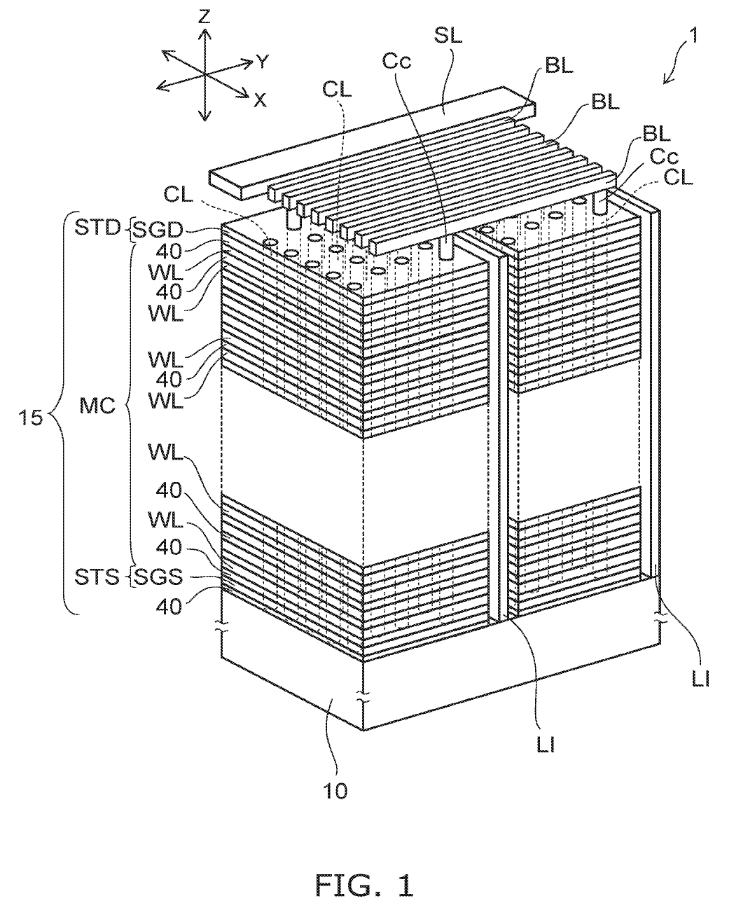

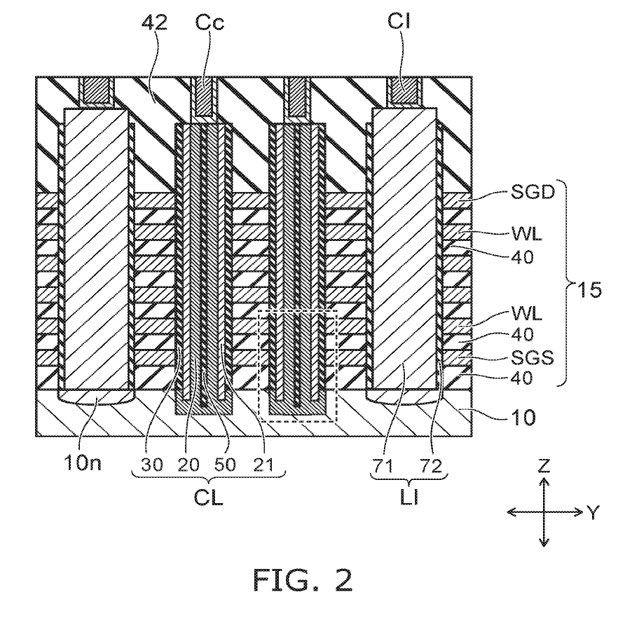

An example of the configuration of a memory cell array 1 of the embodiment will now be described with reference to FIG. 1 and FIG. 2.

FIG. 1 is a schematic perspective view of the memory cell array 1 of the embodiment. In FIG. 1, the insulating layers on the stacked body, etc., are not shown for easier viewing of the drawing.

In FIG. 1, two mutually-orthogonal directions parallel to a major surface of a substrate 10 are taken as an X-direction and a Y-direction; and a direction orthogonal to both the X-direction and the Y-direction is taken as a Z-direction (a stacking direction).

FIG. 2 is a schematic cross-sectional view of the semiconductor memory device of the embodiment. The upper layer interconnects are not shown in FIG. 2 and subsequent drawings.

As shown in FIG. 1 and FIG. 2, the memory cell array 1 includes a stacked body 15, multiple columnar portions CL, an interconnect layer LI, and upper layer interconnects. Bit lines BL and a source layer SL are shown in FIG. 1 as the upper layer interconnects.

The stacked body 15 is provided on the substrate 10. The stacked body 15 includes multiple electrode layers WL, multiple insulating layers 40, a source-side selection gate SGS, and a drain-side selection gate SGD.

The multiple electrode layers WL are stacked with the multiple insulating layers 40 interposed. The multiple insulating layers 40 include, for example, an air gap (a void). The number of stacks of electrode layers WL shown in the drawing is an example; and the number of stacks of electrode layers WL is arbitrary.

The source-side selection gate SGS is provided on the substrate 10 with the insulating layer 40 interposed. The drain-side selection gate SGD is provided in the uppermost layer of the stacked body 15. The multiple electrode layers WL are provided between the source-side selection gate SGS and the drain-side selection gate SGD.

The electrode layer WL includes a metal. The electrode layer WL includes, for example, at least one of tungsten, molybdenum, titanium nitride, or tungsten nitride and may include silicon or a metal silicide. The source-side selection gate SGS and the drain-side selection gate SGD include the same material as the electrode layer WL.

Although the thickness of one layer of the drain-side selection gate SGD and the source-side selection gate SGS normally is thicker than the thickness of one layer of the electrode layers WL, the thickness of one layer of the drain-side selection gate SGD and the source-side selection gate SGS may be about the same as or thinner than the thickness of one layer of the electrode layers WL. Each of the selection gates (SGD and SGS) may be provided not as one layer but as multiple layers. Here, “thickness” refers to the thickness in the stacking direction of the stacked body 15 (the Z-direction).

The multiple columnar portions CL that extend in the Z-direction are provided inside the stacked body 15. For example, the columnar portions CL are provided in circular columnar or elliptical columnar configurations. For example, the multiple columnar portions CL are provided in a staggered lattice configuration. Or, the multiple columnar portions CL may be provided in a square lattice configuration along the X-direction and the Y-direction. The columnar portions CL are electrically connected to the substrate 10.

The structures of the columnar portion CL and the interconnect layer LI will now be described using the cross-sectional view of FIG. 2. As shown in FIG. 2, the columnar portion CL includes a channel body 20 (a first semiconductor film), a cover film 21 (a second semiconductor film), a memory film 30 (a first insulating film), and a core insulating film 50 (a second insulating film). The memory film 30 is provided between the electrode layer WL and the channel body 20; and the cover film 21 is provided between the channel body 20 and the memory film 30. For example, an oxide film may be provided between the channel body 20 and the cover film 21.

The memory film 30 surrounds the cover film 21, the channel body 20, and the core insulating film 50. The memory film 30, the cover film 21, the channel body 20, and the core insulating film 50 extend in the Z-direction. The core insulating film 50 is provided on the inner side of the channel body 20.

The channel body 20 and the cover film 21 are, for example, silicon films having silicon as major components and include, for example, polysilicon. The core insulating film 50 includes, for example, a silicon oxide film and may include an air gap.

As shown in FIG. 1, the interconnect layer LI that extends in the X-direction and the Z-direction is provided inside the stacked body 15 and divides the adjacent stacked bodies 15. Further, the interconnect layer LI multiply extends similarly in the Y-direction as well (not shown for the Y-direction) at the periphery of the memory cell array 1. That is, when the memory cell array 1 is viewed from above, the interconnect layer LI has a structure provided in a matrix configuration. Therefore, the stacked body 15 has a structure of being divided into a matrix configuration by the interconnect layer LI.

As shown in FIG. 2, the interconnect layer LI includes a conductive film 71 and an insulating film 72. The insulating film 72 is provided on the side wall of the interconnect layer LI. The conductive film 71 is provided on the inner side of the insulating film 72.

The lower end of the interconnect layer LI contacts a semiconductor portion 10n of the substrate 10. The interconnect layer LI may be electrically connected, via the substrate 10, to the channel body 20 inside the columnar portion CL. The upper end of the interconnect layer LI is electrically connected to the source layer SL via a contact unit CI.

The multiple bit lines BL (e.g., the metal films) are provided on the stacked body 15. The multiple bit lines BL are separated from each other in the X-direction and extend in the Y-direction. Each of the bit lines BL is connected to one of the multiple channel bodies 20 selected from each of the regions separated with the interconnect layer LI interposed in the Y-direction.

The upper end of the channel body 20 is electrically connected to the bit line BL via a contact unit Cc. The lower end of the channel body 20 contacts the substrate 10.

A drain-side selection transistor STD is provided at the upper end portion of the columnar portion CL; and a source-side selection transistor STS is provided at the lower end portion of the columnar portion CL.

Memory cells MC, the drain-side selection transistor STD, and the source-side selection transistor STS are vertical transistors that can cause a current to flow in the stacking direction of the stacked body 15 (the Z-direction).

The selection gates SGD and SGS function respectively as gate electrodes (control gates) of the selection transistors STD and STS. An insulating film (the memory film 30) that functions as the gate insulator films of the selection transistors STD and STS is provided between the channel body 20 and the selection gates SGD and SGS.

The multiple memory cells MC in which the electrode layers WL of each layer are control gates are provided between the drain-side selection transistor STD and the source-side selection transistor STS.

The multiple memory cells MC, the drain-side selection transistor STD, and the source-side selection transistor STS are connected in series by the channel body 20 and are included in one memory string. The multiple memory cells MC are provided three-dimensionally in the X-direction, the Y-direction, and the Z-direction by providing the memory strings in, for example, a staggered lattice configuration in a planar direction parallel to the X-Y plane.

The semiconductor memory device of the embodiment can freely and electrically erase/program data and can retain the memory content even when the power supply is OFF.

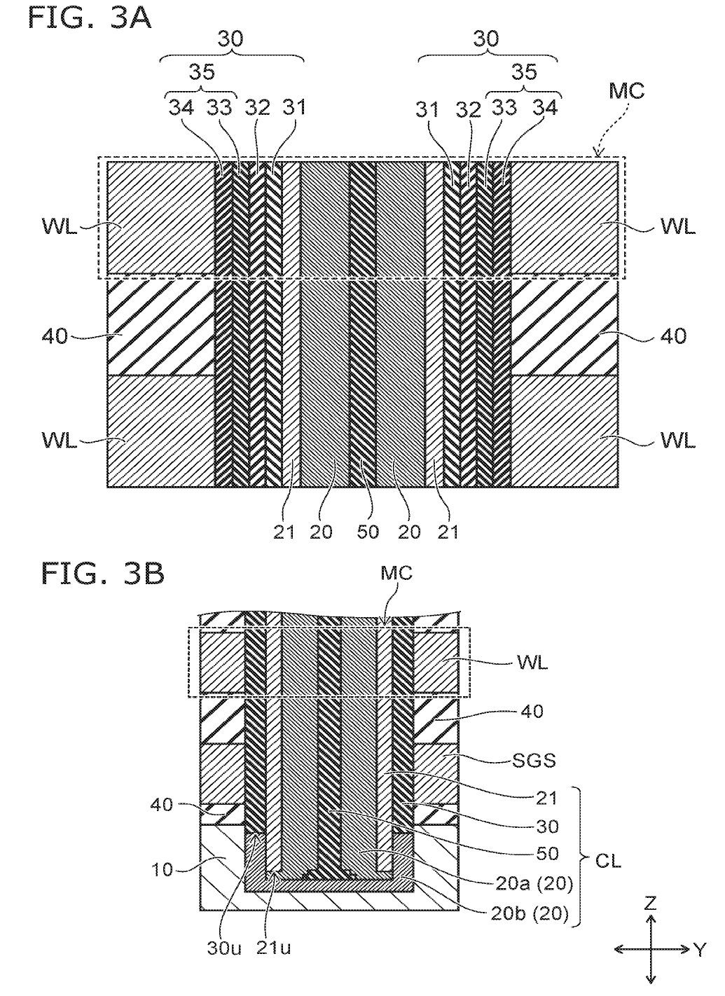

An example of the memory cell MC of the embodiment will now be described with reference to FIG. 3A.

FIG. 3A is an enlarged schematic cross-sectional view of a portion of the columnar portion CL of the embodiment.

The memory cell MC is, for example, a charge trap memory cell and includes the electrode layer WL, the memory film 30, the cover film 21, the channel body 20, and the core insulating film 50.

The memory film 30 includes a charge storage film 32, a tunneling insulating film 31 (a first insulating unit), and a blocking insulating film 35 (a second insulating unit). The tunneling insulating film 31 is provided in contact with the cover film 21. The charge storage film 32 is provided between the blocking insulating film 35 and the tunneling insulating film 31. The blocking insulating film 35 is provided between the charge storage film 32 and the electrode layer WL.

The channel body 20 functions as a channel of the memory cell MC; and the electrode layer WL functions as a control gate of the memory cell MC. The charge storage film 32 functions as a data storage layer and stores charge injected from the channel body 20. The blocking insulating film 35 prevents the charge stored in the charge storage film 32 from diffusing into the electrode layer WL. In other words, the memory cells MC that have structures in which the control gate surrounds the periphery of the channel are formed at the intersections between the channel body 20 and each of the electrode layers WL.

The blocking insulating film 35 includes, for example, a capping film 34 and a blocking film 33. The blocking film 33 is provided between the capping film 34 and the charge storage film 32. The blocking film 33 is, for example, a silicon oxide film.

The capping film 34 is provided in contact with the electrode layer WL. The capping film 34 includes a film having a dielectric constant that is higher than that of the blocking film 33.

By providing the capping film 34 in contact with the electrode layer WL, back-tunneling electrons injected from the electrode layer WL when erasing can be suppressed; and the charge blocking properties can be increased. Although not shown in FIG. 3A, the blocking insulating film 35 may be provided as one body between the electrode layer WL and the insulating layers 40 and between the electrode layer WL and the charge storage film 32.

The charge storage film 32 has many trap sites that trap charge. The charge storage film 32 includes, for example, at least one of a silicon nitride film or hafnium oxide.

The tunneling insulating film 31 is used as a potential barrier when the charge is injected from the channel body 20 into the charge storage film 32 or when the charge stored in the charge storage film 32 diffuses into the channel body 20. The tunneling insulating film 31 includes, for example, a silicon oxide film.

Or, a stacked film (an ONO film) that has a structure in which a silicon nitride film is interposed between a pair of silicon oxide films may be used as the tunneling insulating film 31. In the case where the ONO film is used as the tunneling insulating film 31, compared to a single-layer of the silicon oxide film, the erasing operation is performed using a low electric field.

An example of the configuration of the semiconductor memory device of the embodiment will now be described with reference to FIG. 3B.

FIG. 3B is a schematic cross-sectional view of the dotted line portion shown in FIG. 2.

As shown in FIG. 3B, the channel body 20 includes a first portion 20a and a second portion 20b, the first portion 20a and the second portion 20b have crystal structures that are different from each other. The first portion 20a extends in the Z-direction and is provided as one body inside the stacked body 15 and inside the substrate 10.

The second portion 20b is provided inside the substrate 10 and contacts the substrate 10. The second portion 20b is provided between the first portion 20a and the substrate 10. The second portion 20b contacts the substrate 10; and the first portion 20a is separated from the substrate 10 with the second portion 20b interposed.

The second portion 20b is provided as one body between the substrate 10 and the lower surface of the first portion 20a and between the substrate 10 and the side surface of the cover film 21. The lower surface of the first portion 20a is covered with the second portion 20b. Although not shown in FIG. 3B, for example, the first portion 20a may be provided between the second portion 20b and the side surface of the cover film 21.

As shown in the manufacturing method described below, for example, polysilicon that is formed by heating (crystallization annealing of) amorphous silicon is used as the channel body 20. At this time, the second portion 20b that is provided to be proximal to the substrate 10 is crystallized by inheriting the crystal structure of the substrate 10. On the other hand, the first portion 20a that is separated from the substrate 10 is crystallized by, for example, inheriting the crystal structure of the cover film 21.

In other words, the crystal structure that is formed when performing the crystallization annealing of the amorphous silicon is different between the locations where the amorphous silicon is provided. Here, because the substrate 10 is monocrystalline, the likelihood is high that the amorphous silicon proximal to the substrate 10 will be monocrystallized, or polycrystallized to be substantially monocrystalline. On the other hand, for the amorphous silicon separated from the substrate 10, the likelihood of being monocrystallized is low; and the likelihood of being polycrystallized (to become polysilicon) is high.

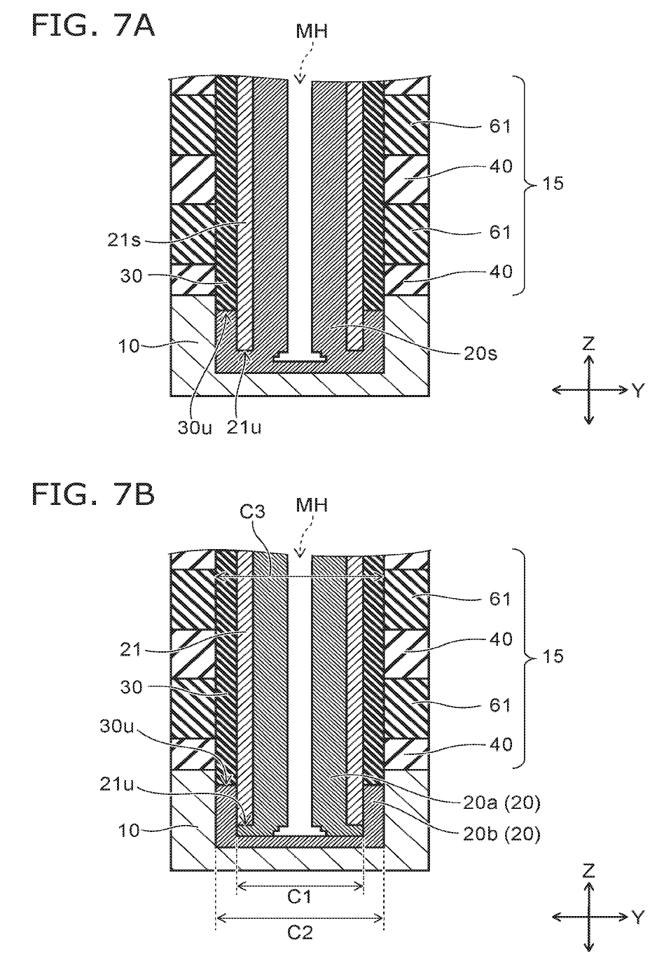

Therefore, the second portion 20b has a crystal structure (a second crystal structure) that is substantially equal to the crystal structure of the substrate 10 (here, monocrystalline). On the other hand, the first portion 20a has a crystal structure (a first crystal structure) that is different from the crystal structure of the substrate 10. These crystal structures are elaborated in reference to FIG. 7B. The “second crystal structure” is one of a monocrystalline crystal structure or a crystal structure having monocrystalline as a major structure; and the “first crystal structure” is one of a polycrystalline crystal structure or a crystal structure having polycrystalline as a major structure.

The memory film 30 has a lower surface 30u contacting the second portion 20b. The lower surface 30u is provided at a height that is not more than the height of the surface of the substrate 10 contacting the stacked body 15. The difference between the lower surface 30u and the height of the surface of the substrate 10 contacting the stacked body 15 is, for example, 20 nm or less. Here, “height” refers to the height in the Z-direction with reference to the surface of the substrate 10 that is in contact with the insulating layer 41, and refers to the position being higher from the substrate 10 toward the stacked body 15.

The cover film 21 has a lower surface 21u contacting the channel body 20. The lower surface 21u is provided at a height that is lower than the height of the lower surface 30u of the memory film 30 and higher than the height of the lower surface of the second portion 20b. The cover film 21 is surrounded with the channel body 20 at a height that is lower than the lower surface 30u of the memory film 30.

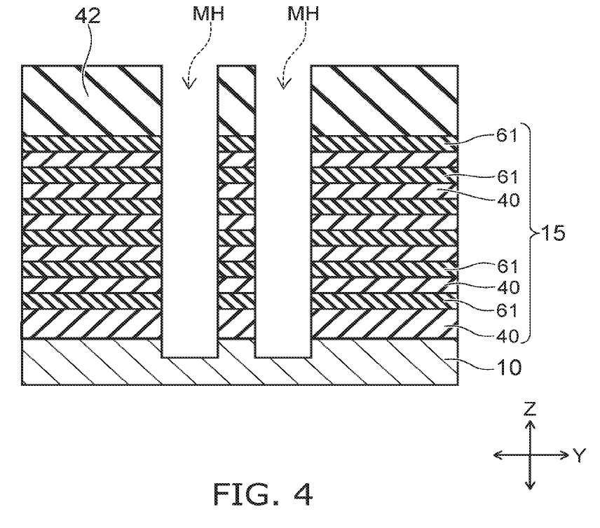

An example of a method for manufacturing the semiconductor memory device of the embodiment will now be described with reference to FIG. 4 to FIG. 7B.

First, after forming an element separation region on the substrate 10, peripheral transistors (not shown) are formed.

Then, as shown in FIG. 4, the insulating layer 40 is formed on the substrate 10. Multiple sacrificial layers 61 (multiple first layers) are stacked with multiple insulating layers 40 interposed on the insulating layer 40. Thereby, the stacked body 15 is formed. An insulating layer 42 is formed on the stacked body 15.

The sacrificial layer 61 includes, for example, a silicon nitride film. The insulating layer 40 includes, for example, a silicon oxide film.

Subsequently, a hole MH that pierces the insulating layer 42 and the stacked body 15 and reaches the interior of the substrate 10 is made. For example, RIE (Reactive Ion Etching) using a not-shown mask is used as the method for making the hole MH. Thereby, the substrate 10 at the bottom surface of the hole MH is exposed.

Subsequently, etching is performed further to a prescribed depth of the substrate 10.

Also, the substrate 10 is not directly patterned using anisotropic etching such as RIE, etc., in the subsequent processes. Therefore, the depth fluctuation of the channel body 20 formed inside the substrate 10 can be reduced; and the fluctuation of the contact resistance can be reduced.

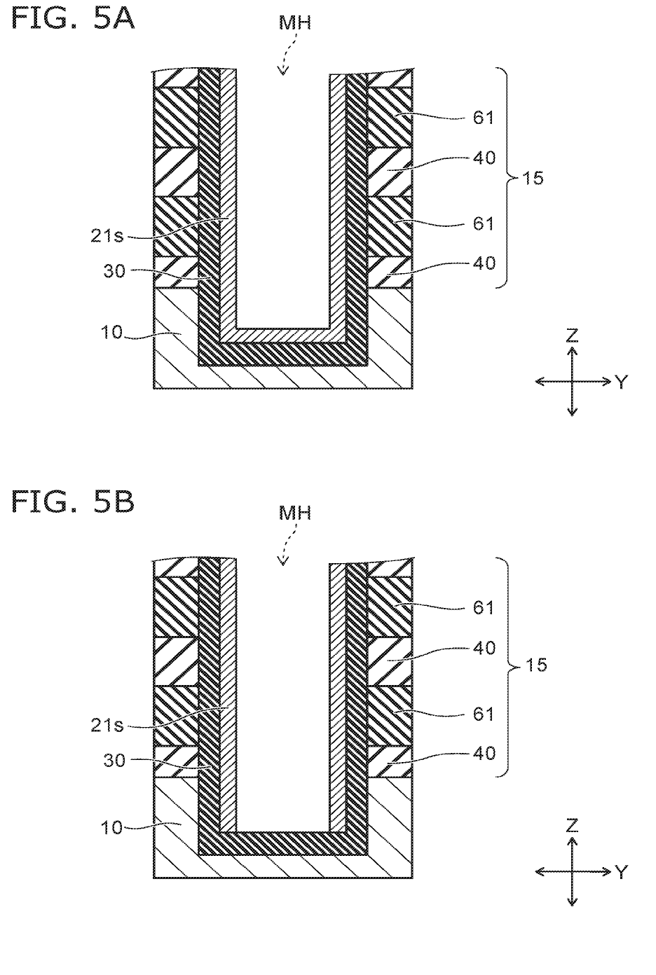

Then, as shown in FIG. 5A, the memory film 30 that includes the charge storage film 32 shown in FIG. 3A is formed inside the hole MH. Thereby, the memory film 30 is formed as one body on the wall surfaces (the side wall and the bottom surface) of the hole MH. A cover film 21s is formed on the memory film 30 inner side. For example, the cover film 21s is a silicon-based amorphous film such as amorphous silicon, etc.

As shown in FIG. 5B, the cover film 21s that is formed on the bottom surface of the hole MH is removed; and the memory film 30 at the bottom surface of the hole MH is exposed. For example, RIE using a chlorine-based gas is used as the method for removing the cover film 21 at the bottom surface of the hole MH; and conditions having a high selectivity with respect to the insulating film (the memory film 30) are used.

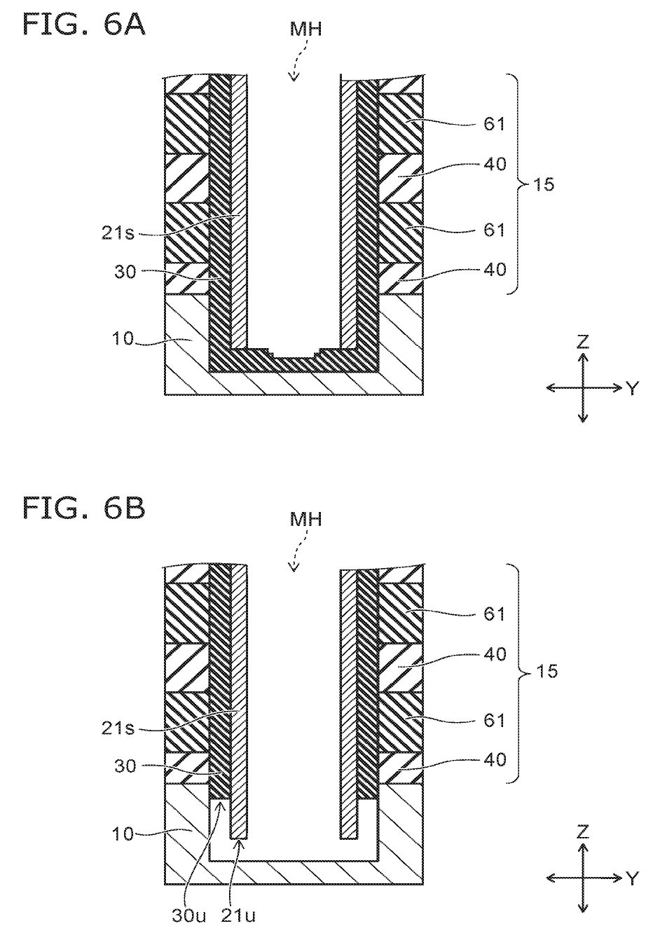

Further, as shown in FIG. 6A, etching is performed so that a portion of the memory film 30 is removed and a portion of the memory film 30 remains on the substrate 10. The portion of the memory film 30 is caused to remain so that etching damage of the surface of the substrate 10 does not occur in the RIE.

Here, in the case where the etching is performed to the surface or interior of the substrate 10 and the etching is performed without causing the memory film 30 to remain, a defect portion due to the etching damage is formed in the surface of the substrate 10 that is etched. Thereby, trap levels and fixed charge concentrate in the defect portion which may cause an increase of the contact resistance and cause a decrease of the sense current, a decrease of the hole current in the erasing operation, etc. Also, when a reverse bias is applied to the p-n junction between the interconnect layer LI and the substrate 10, a depletion layer extends to the columnar portion CL bottom portion; electron-hole pairs are generated due to the trap levels of the defect portion contacting the channel body 20; and the junction leakage may degrade.

Therefore, here, the patterning by etching using RIE is stopped inside the memory film 30; and the substrate 10 surface is not subjected to etching damage.

Continuing, to provide contact with the substrate 10, as shown in FIG. 6B, a portion of the memory film 30 formed inside the substrate 10 is removed via the hole MH by an etching method that is different from that of FIG. 6A described above. Specifically, for example, isotropic etching using conditions having a high selectivity with respect to silicon is used as the method for removing the memory film 30. As the isotropic etching, for example, a method (e.g., the Siconi Process™, etc.) is used in which one cycle of etching of an etchant reaction and heating at a low temperature (e.g., about 200° C.) is multiply implemented. For example, gas types of ammonia (NH₃) and nitrogen trifluoride (NF₃) are used in the etching. Other than the description recited above, for example, wet etching using hot phosphoric acid, etc., may be used.

Thereby, the memory film 30 that remains on the surface of the substrate 10 at the bottom portion of the hole MH also is removed; and the lower surface 21u and side surface of the cover film 21s and the lower surface 30u of the memory film 30 are exposed. The height of the lower surface 30u of the memory film 30 is lower than the height of the surface of the substrate 10 contacting the stacked body 15 and higher than the height of the lower surface 21u of the cover film 21s. At this time, compared to the case where the memory film 30 is removed by anisotropic etching such as RIE, etc., the surface area of the portion of the substrate 10 exposed inside the hole MH becomes large. In other words, the memory film 30 formed on the bottom surface portion and the side surface portion of the hole MH made in FIG. 4 is removed by etching; and the substrate 10 surface is exposed at the bottom surface portion and the side surface portion of the hole MH.

Accordingly, when solid phase epitaxy of a channel body 20s inside the hole MH is performed, the surface area of the portion of the channel body 20s contacting the substrate 10 can be formed to be large; and the contact resistance can be reduced.

Also, high-quality crystallization is possible because the solid phase growth is performed from the hole MH bottom surface that is flat and has a width of the size of the hole MH diameter. In other words, the lower surface of the channel body 20 formed by solid phase growth in a process described below is provided to be flat; and as viewed from the Z-direction, the maximum diameter of the lower surface of the channel body 20 is equal to the maximum diameter of the memory film 30.

As shown in FIG. 7A, the channel body 20s is formed on the inner side of the cover film 21s. The channel body 20s is a silicon-based amorphous film such as amorphous silicon, etc., and the channel body 20s is formed as one body to contact the lower surface 21u and side surface of the cover film 21s, the lower surface 30u of the memory film 30, and the substrate 10. The side surface of the cover film 21s is surrounded with the channel body 20s.

As shown in FIG. 7B, heating (crystallization annealing of) the channel body 20s and the cover film 21s is performed. Thereby, the channel body 20 and the cover film 21 that are crystallized are formed. At this time, the first portion 20a and the second portion 20b that have different crystal structures are formed in the channel body 20.

The second portion 20b of the channel body 20 is formed in contact with the substrate 10. At least the portion of the second portion 20b contacting the substrate 10 can be crystallized by inheriting the crystal structure of the substrate 10 of the foundation by solid phase epitaxy, etc. In other words, if the substrate 10 is monocrystalline, the portion of the second portion 20b contacting the substrate 10 also may be monocrystallized.

Ideally, it is desirable for the entire surface of the second portion 20b contacting the substrate 10 to be monocrystallized or for monocrystalline to be dominant over a prescribed film thickness (e.g., about 15 nm). In this case, for example, the crystal structure of the entire second portion 20b is a monocrystalline crystal structure.

However, actually, this is not limited to being monocrystallized in this way. That is, a portion that is monocrystallized and a polycrystalline portion being substantially monocrystalline may coexist in the second portion 20b. However, in such a case, the crystal structure of the entire second portion 20b is a crystal structure having monocrystalline as a major structure. Here, “crystal structure having monocrystalline as a major structure” refers to, for example, 70% or more of the prescribed film thickness of the second portion 20b being a monocrystalline region.

On the other hand, the channel body 20 and the cover film 21 that are separated from the substrate 10 have a portion not reached by the solid phase growth from the silicon of the substrate 10; and polysilicon that is made of a structure of crystallites of about several tens of nm to about 200 nm is formed and monocrystallization does not occur in the portions due to the heating (the crystallization annealing). The polysilicon portion of the channel body 20 that is separated from the substrate 10 is referred to as the first portion 20a. In this case, the crystal structure of the entire first portion 20a is a polycrystalline crystal structure.

However, actually, the entire first portion 20a is not limited to being polycrystallized. That is, a portion that is polycrystallized and a portion that is monocrystallized may coexist in the first portion 20a. In such a case, the crystal structure of the entire first portion 20a is a crystal structure having polycrystalline as a major structure. Here, “crystal structure having polycrystalline as a major structure” refers to, for example, a region where 70% or more of a prescribed film thickness (e.g., about 15 nm) of the first portion 20a is polycrystalline.

Also, the crystallites of the first portion 20a form not only from the substrate 10 side but also from, for example, the side surface of the cover film 21 contacting an oxide film (the memory film 30); and the crystallites of the first portion 20a are crystallized by inheriting the crystal structure of the cover film 21.

The size of the crystallites can be measured by using, for example, X-ray analysis, EBSD (Electron Back Scatter Diffraction Patterns), a TEM (Transmission Electron Microscope), etc.

Also, when removing the memory film 30 that is on the hole MH, first, a portion of the memory film 30 is etched by, for example, anisotropic etching using RIE, etc.; and a portion of the memory film 30 is caused to remain. Subsequently, the memory film 30 is removed to expose the surface of the substrate 10 by isotropic etching such as wet etching, etc., that has less damage to the substrate 10 than anisotropic etching. Therefore, a defect portion (an interface damage portion, a stepped portion, or the like) is not formed by the anisotropic etching such as RIE, etc., between the substrate 10 and the lower surface of the second portion 20b of the channel body 20 formed subsequently.

Conversely, for example, in the case where the defect portion recited above is formed between the substrate 10 and the amorphous silicon film used to form the channel body 20, the monocrystalline structure of the substrate 10 is not inherited as-is by the region of the lower surface of the amorphous silicon film contacting the substrate 10 at the defect portion in the crystallization annealing; and a polycrystalline crystal structure is formed in the region. Thereby, a region that has a different crystal structure exists at the defect portion vicinity in the channel body 20; and the resistance of the channel body 20 contacting the substrate 10 may increase locally.

On the other hand, according to the embodiment as described above, because the defect portion is not formed at the lower surface of the second portion 20b contacting the substrate 10, the monocrystalline structure is formed easily by inheriting the monocrystalline structure of the substrate 10 as-is. Therefore, a monocrystalline crystal structure can be formed as one body in the entire lower surface of the second portion 20b. In other words, it is possible to suppress the local increase of the resistance at the lower surface of the channel body 20.

When viewed from the Z-direction, a maximum diameter C1 of the first portion 20a is, for example, less than a maximum diameter C2 of the lower surface of the second portion 20b and a maximum diameter C3 of the memory film 30. For example, the side surface of the second portion 20b is coplanar with the side surface of the memory film 30; and the maximum diameter C2 of the lower surface of the second portion 20b is equal to the maximum diameter C3 of the memory film 30.

Then, as shown in FIG. 3B, the core insulating film 50 is formed on the inner side of the channel body 20. Thereby, the columnar portion CL is formed.

Subsequently, a slit is made in the stacked body 15; and the multiple sacrificial layers 61 are removed via the slit. The multiple electrode layers WL, the source-side selection gate SGS, and the drain-side selection gate SGD shown in FIG. 1 and FIG. 2 are formed in the portions where the multiple sacrificial layers 61 were removed.

Then, the interconnect layer LI is formed by forming the insulating film 72 and the conductive film 71 inside the slit. The contact units CI and Cc are formed on the interconnect layer LI and the columnar portion CL. Subsequently, the upper layer interconnects, etc., are formed; and the semiconductor memory device of the embodiment is formed.

A method may be used in which the electrode layers WL and the source-side selection gate SGS are formed initially instead of forming the sacrificial layers 61.

Thus, according to the embodiment, the contact resistance between the lower surface of the channel body 20 and the substrate 10 can be reduced; and it is possible to improve the electrical characteristics of the device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device, comprising:
a substrate;
a stacked body provided on the substrate, the stacked body including a plurality of electrode layers stacked with an insulating layer interposed;
a first semiconductor film provided as one body inside the stacked body and inside the substrate, the first semiconductor film extending in a stacking direction of the stacked body, the first semiconductor film including
a first portion provided as one body inside the stacked body, the first portion having a first crystal structure different from a crystal structure of the substrate, and
a second portion provided between the first portion and the substrate, the second portion contacting the substrate and having a second crystal structure different from the first crystal structure;
a first insulating film provided between the first semiconductor film and the stacked body, the first insulating film extending in the stacking direction and having a lower surface contacting the second portion, the lower surface provided at a height not higher than a height of a surface of the substrate contacting the stacked body; and
a second semiconductor film provided between the first insulating film and the first portion of the first semiconductor film, the second semiconductor film extending in the stacking direction and having a lower surface provided at a height lower than the height of the lower surface of the first insulating film.

2. The semiconductor memory device according to claim 1, wherein a crystal structure of one of a lower surface or an entire surface of the second portion contacting the substrate is a monocrystalline crystal structure.

3. The semiconductor memory device according to claim 1, wherein
a lower surface of the second portion contacting the substrate is provided to be flat, and
a maximum diameter of the second portion is equal to a maximum diameter of the first insulating film as viewed from the stacking direction.

4. The semiconductor memory device according to claim 1, wherein
a crystal structure of the entire first portion is the first crystal structure, and
a crystal structure of the entire second portion is the second crystal structure.

5. The semiconductor memory device according to claim 4, wherein the second crystal structure is one of a monocrystalline crystal structure or a crystal structure having monocrystalline as a major structure.

6. The semiconductor memory device according to claim 4, wherein the first crystal structure is one of a polycrystalline crystal structure or a crystal structure having polycrystalline as a major structure.

7. The semiconductor memory device according to claim 4, wherein the second crystal structure is a monocrystalline crystal structure.

8. The semiconductor memory device according to claim 4, wherein the first crystal structure is a polycrystalline crystal structure.

9. The semiconductor memory device according to claim 1, wherein
the first insulating film includes:
a charge storage film provided between the second semiconductor film and the plurality of electrode layers;
a first insulating unit provided between the charge storage film and the second semiconductor film; and
a second insulating unit provided between the charge storage film and the plurality of electrode layers.

10. The semiconductor memory device according to claim 1, wherein the first portion is separated from the substrate with the second portion interposed.

11. The semiconductor memory device according to claim 1, wherein the second portion is provided as one body between the substrate and a lower surface of the first portion and between the substrate and a side surface of the second semiconductor film.

12. The semiconductor memory device according to claim 1, wherein the height of the lower surface of the second semiconductor film is higher than a height of a lower surface of the second portion.

13. The semiconductor memory device according to claim 1, wherein the second semiconductor film is surrounded with the first semiconductor film at a height lower than the lower surface of the first insulating film.

14. The semiconductor memory device according to claim 1, wherein a difference between the height of the lower surface of the first insulating film and the height of the surface of the substrate contacting the stacked body is 20 nm or less.

15. The semiconductor memory device according to claim 1, wherein a lower surface of the first portion is covered with the second portion.

16. The semiconductor memory device according to claim 1, wherein a maximum diameter of the first portion is less than a maximum diameter of the second portion as viewed from the stacking direction.

17. The semiconductor memory device according to claim 1, wherein a maximum diameter of the first portion is less than a maximum diameter of the first insulating film as viewed from the stacking direction.

18. A method for manufacturing a semiconductor memory device, comprising:
forming a stacked body on a substrate, the stacked body including a plurality of first layers stacked with an insulating layer interposed;
making a hole piercing the stacked body to reach the substrate;
forming a first insulating film on an inner wall of the hole, the first insulating film including a charge storage film;
forming a second semiconductor film on an inner side of the first insulating film;
removing the second semiconductor film formed on a bottom surface of the hole;
removing the first insulating film exposed at the bottom surface of the hole to form a lower surface of the first insulating film between a height of a surface of the substrate contacting the stacked body and a height of a lower surface of the second semiconductor film;
forming a first semiconductor film on an inner side of the second semiconductor film and at a portion where the first insulating film is removed; and
subsequently performing heating.

19. The method for manufacturing the semiconductor memory device according to claim 18, wherein the removing of the second semiconductor film includes removing the second semiconductor film using RIE having a condition of a high selectivity with respect to the first insulating film.

20. The method for manufacturing the semiconductor memory device according to claim 19, wherein
the heating of the first semiconductor film and the second semiconductor film includes forming a first portion and a second portion of the first semiconductor film,
the first portion is separated from the substrate and has a first crystal structure different from a crystal structure of the substrate, and
the second portion is formed between the first portion and the substrate and has a second crystal structure different from the first crystal structure in a portion contacting the substrate.
